(19) United States
(12) Patent Application Publication
(10) Pub. No.: US 2026/0035292 A1
(43) Pub. Date: Feb. 5, 2026

(54) APPARATUS FOR MANUFACTURING DISPLAY APPARATUS

(71) Applicants: Samsung Display Co., LTD., Yongin-si (KR); IUCF-HYU (Industry-University Cooperation Foundation Hanyang University), Seoul (KR)

(72) Inventors: Juil Hwang, Yongin-si (KR); Hyungsik Kim, Yongin-si (KR); Kwanggeol Lee, Seoul (KR); Seunghyun Bang, Seoul (KR); Kisang Lee, Yongin-si (KR); Woohyun Jung, Yongin-si (KR)

(21) Appl. No.: 19/289,607

(22) Filed: Aug. 4, 2025

(30) Foreign Application Priority Data
Aug. 5, 2024 (KR) 10-2024-0104125

(51) Int. Cl. C03C 15/00; H10K 71/00

(52) U.S. Cl. CPC C03C 15/00; H10K 71/621

(57) ABSTRACT

An apparatus for manufacturing a display apparatus includes an intense-light irradiation unit configured to irradiate an intense light to a target, an etching unit configured to etch the target so that a hole is defined in the target to which the intense light is irradiated, and a controller including an etching controller configured to control the etching unit, wherein the etching unit includes an etching module including a first chamber in which a first liquid is stored as an etching solution, an etching stage on which the target is seated, and a target sensor unit configured to measure a state of a surface of the target, an ultrasonic module configured to vibrate the etching module by generating ultrasonic waves, and a stirring module configured to stir the first liquid. The etching controller calculates an etching accuracy of the target based on information measured by the target sensor unit, and control an operation of the stirring module, based on the etching accuracy.

This application claims priority to Korean Patent Application No. 10-2024-0104125, filed on Aug. 5, 2024, and all the benefits accruing therefrom under 35 U.S.C. § 119, the content of which in its entirety is herein incorporated by reference.

### BACKGROUND

### 1. Field

Embodiments relate to an apparatus, and more particularly, to an apparatus for manufacturing a display apparatus.

### 2. Description of the Related Art

Mobility-based electronic devices are widely used. Recently, tablet personal computers, in addition to relatively small electronic devices such as mobile phones, have been widely used as mobile electronic devices.

A mobile electronic device includes a display apparatus for providing visual information such as an image to a user, in order to support various functions. Recently, as other components for driving a display apparatus have been miniaturized, the proportion taken up by display apparatuses in electronic devices has gradually increased, and structures that are bendable from a flat state to have a predetermined angle are being developed.

In this case, an etching process is performed after laser treatment in order to efficiently process a substrate used in a display apparatus.

### SUMMARY

Embodiments include an apparatus for manufacturing a display apparatus for quickly and efficiently processing a target while maintaining a predetermined level of precision.

However, these problems are examples and problems to be solved by the disclosure are not limited thereto.

Additional features will be set forth in part in the description which follows and, in part, will be apparent from the description, or may be learned by practice of the presented embodiments.

In embodiments, an apparatus for manufacturing a display apparatus includes an intense-light irradiation unit configured to irradiate an intense light to a target, an etching unit configured to etch the target so that a hole is defined in the target to which the intense light is irradiated, and a controller including an etching controller configured to control the etching unit, wherein the etching unit includes an etching module including a first chamber in which a first liquid is stored as an etching solution, an etching stage on which the target is seated, and a target sensor unit configured to measure a state of a surface of the target, an ultrasonic module configured to vibrate the etching module by generating ultrasonic waves, and a stirring module configured to stir the first liquid. The etching controller calculates an etching accuracy of the target based on information measured by the target sensor unit, and control an operation of the stirring module, based on the etching accuracy.

In the illustrated embodiment, the etching controller may be further configured to, when the etching accuracy is equal to or greater than a pre-determined value, operate each of the ultrasonic module and the stirring module.

In the illustrated embodiment, the etching controller may be further configured to, when the etching accuracy is less than a pre-determined value, operate the ultrasonic module and turn off the stirring module.

In the illustrated embodiment, the etching controller may be further configured to calculate the etching accuracy based on an increment in a width of the hole over time.

In the illustrated embodiment, the target sensor unit may include an image sensor.

In the illustrated embodiment, the etching controller may be further configured to calculate whether the hole is defined in the target based on information measured by the target sensor unit.

In the illustrated embodiment, the etching controller may be further configured to, when it is determined that the hole is defined in the target, turn off the ultrasonic module and the stirring module.

In the illustrated embodiment, the first liquid may include at least one of hydrogen fluoride (“HF”) and hydrochloric acid (“HCl”).

In the illustrated embodiment, the first liquid may include a solution in which HF and HCl are mixed at a ratio of 7:3.

In the illustrated embodiment, the target may include a transparent glass material.

In embodiments, an apparatus for manufacturing a display apparatus includes an intense-light irradiation unit configured to irradiate an intense light to generate microcracks in a target along an imaginary first line, an etching unit configured to etch the target so that a hole is defined in the target around the imaginary first line, and a controller including an etching controller configured to control the etching unit, wherein the etching unit includes an etching module including a first chamber in which a first liquid is stored as an etching solution, an etching stage that is disposed in the first chamber and on which the target is seated, and a target sensor unit configured to measure a state of a surface of the target, an ultrasonic module configured to vibrate the etching module by generating ultrasonic waves, and a stirring module configured to stir the first liquid.

In the illustrated embodiment, the ultrasonic module may include a second chamber in which the etching module is disposed and a second liquid is stored so that at least a part of the etching module is immersed, and an ultrasonic generator disposed in the second chamber and configured to generate ultrasonic waves so that the second liquid vibrates.

In the illustrated embodiment, the stirring module may include a blade at least partially immersed in the first liquid, and a driving unit configured to provide a driving force to the blade so that the blade moves.

In the illustrated embodiment, the etching controller may calculate an etching accuracy of the target based on information measured by the target sensor unit, and control an operation of the stirring module, based on the etching accuracy.

In the illustrated embodiment, the etching controller may be further configured to, when the etching accuracy is equal to or greater than a pre-determined value, operate each of the ultrasonic module and the stirring module.

In the illustrated embodiment, the etching controller may be further configured to, when the etching accuracy is less than a pre-determined value, operate the ultrasonic module and turn off the stirring module.

In the illustrated embodiment, the etching controller may be further configured to calculate the etching accuracy based on an increment in a width of the hole over time.

In the illustrated embodiment, the etching controller may be further configured to calculate whether the hole is defined in the target based on information measured by the target sensor unit.

In the illustrated embodiment, the etching controller may be further configured to, when it is determined that the hole is defined in the target, turn off the ultrasonic module and the stirring module.

In the illustrated embodiment, the target sensor unit may include an image sensor.

Other features and advantages of the disclosure will become more apparent from the drawings, the claims, and the detailed description.

### BRIEF DESCRIPTION OF THE DRAWINGS

The above and other features and advantages of illustrative embodiments will be more apparent from the following description taken in conjunction with the accompanying drawings, in which:

FIG. 1 is a schematic block diagram illustrating an embodiment of an apparatus for manufacturing a display apparatus;

FIG. 2 is a perspective view schematically illustrating an embodiment of a part of an apparatus for manufacturing a display apparatus;

FIG. 3 is a cross-sectional view schematically illustrating an embodiment of a part of an apparatus for manufacturing a display apparatus;

FIG. 4 is a cross-sectional view schematically illustrating an embodiment of a part of an apparatus for manufacturing a display apparatus;

FIG. 5 is a cross-sectional view schematically illustrating an embodiment of a part of a target;

FIGS. 6 and 7 are cross-sectional views schematically illustrating an embodiment of a part of a target;

FIG. 8 is a plan view schematically illustrating an embodiment of a part of a target;

FIG. 9 is a graph illustrating an embodiment of an etching rate and an etching accuracy of a target;

FIG. 10 is a flowchart illustrating an embodiment of a process of etching a target;

FIG. 11 is a schematic plan view illustrating an embodiment of a display apparatus;

FIG. 12 is an equivalent circuit diagram illustrating an embodiment of a pixel circuit included in a display apparatus; and

FIG. 13 is a schematic cross-sectional view illustrating an embodiment of a display apparatus.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When an illustrative embodiment may be implemented differently, a specific process order may be different from the described order. For example, two consecutively described processes may be performed substantially at the same time or may be performed in an order opposite to the described order.

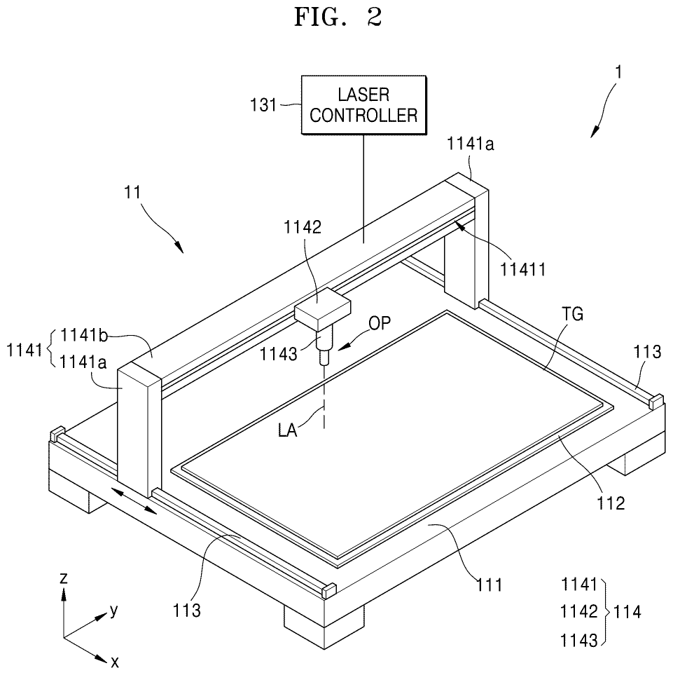

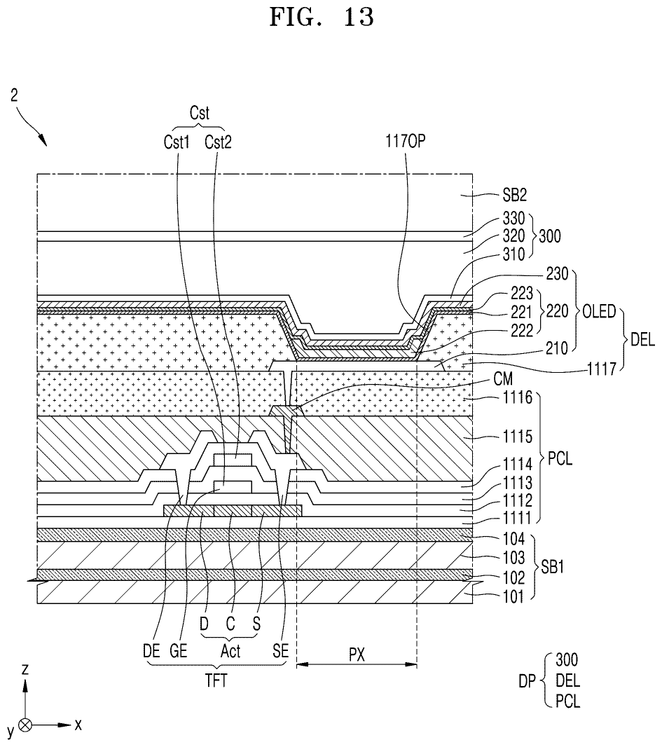

In the specification, a “plan view” refers to a two-dimensional view seen in a direction perpendicular to a target TG (refer to FIG. 2) or a substrate 100 (refer to FIG. 13). That is, “A and B spaced apart from each other in a plan view” means “A and B spaced apart from each other when viewed in a direction perpendicular to the target TG (refer to FIG. 2) or the substrate 100 (refer to FIG. 13)”.

In the specification, a “cross-sectional view” refers to a two-dimensional view cut in a direction perpendicular to the target TG (refer to FIG. 2) or the substrate 100 (refer to FIG. 13). That is, “A and B spaced apart from each other in a plan view” means “A and B spaced apart from each other in a two-dimensional view cut in a direction perpendicular to the target TG (refer to FIG. 2) or the substrate 100 (refer to FIG. 13)”.

The terms such as “controller” and “generator” as used herein may be intended to mean a hardware component such as a circuitry that performs a predetermined function unless particularly defined. The hardware component may include a field-programmable gate array (“FPGA”) or an application-specific integrated circuit (“ASIC”), for example.

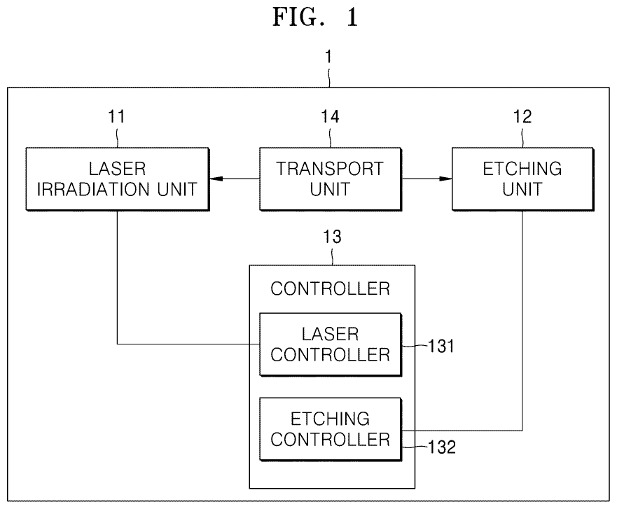

FIG. 1 is a schematic block diagram illustrating an embodiment of an apparatus 1 for manufacturing a display apparatus.

Referring to FIG. 1, the apparatus 1 for manufacturing a display apparatus may include an intense-light irradiation unit (e.g., laser irradiation unit 11), an etching unit 12, a controller 13, and a transport unit 14.

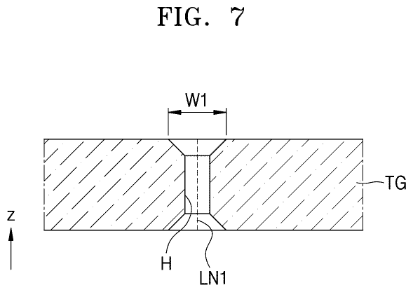

The laser irradiation unit 11 may irradiate an intense light (e.g., laser LA) (refer to FIG. 2) to the target TG (refer to FIG. 2). The etching unit 12 may etch the target TG (refer to FIG. 2) to define a hole H (refer to FIG. 7) in the target TG (refer to FIG. 2) to which the laser LA (refer to FIG. 2) is irradiated. The controller 13 may control the laser irradiation unit 11 and the etching unit 12. The controller 13 may include a laser controller 131 and an etching controller 132. The laser controller 131 may control the laser irradiation unit 11. The etching controller 132 may control the etching unit 12. The transport unit 14 may transport the target TG (refer to FIG. 2). The transport unit 14 may transport the target TG (refer to FIG. 2), to which the laser LA (refer to FIG. 2) is irradiated by the laser irradiation unit 11, to the etching unit 12. Accordingly, the etching unit 12 may etch the target TG (refer to FIG. 2) to which the laser LA (refer to FIG. 2) is irradiated.

FIG. 2 is a perspective view schematically illustrating an embodiment of a part of the apparatus 1 for manufacturing a display apparatus.

In detail, FIG. 2 illustrates the laser irradiation unit 11 and the laser controller 131 of the apparatus 1 for manufacturing a display apparatus.

Referring to FIG. 2, the laser irradiation unit 11 may include a laser support portion 111, a laser stage 112, a guide unit 113, a moving unit 114, and an optical unit OP.

The laser support portion 111 may support the laser stage 112, the guide unit 113, the moving unit 114, and the optical unit OP. The laser support portion 111 may have a plane defined by a first direction (e.g., an x-axis direction) and a second direction (e.g., a y-axis direction).

The laser stage 112 may be disposed on the laser support portion 111, and may have a plane defined by the first direction (e.g., the x-axis direction) and the second direction (e.g., the y-axis direction). The target TG may be seated on the laser stage 112.

In an embodiment, as shown in FIG. 2, a shape of the target TG may have a quadrangular plate shape, for example. In an embodiment, the target TG may have a thin quadrangular shape, e.g., thin rectangular shape, for example. However, this is only an illustrative embodiment, and the target TG may have various shapes. In an embodiment, the target TG may have a circular planar shape, for example.

The target TG may include or consist of a transparent material. In an embodiment, the target TG may include at least one of borosilicate glass, alumino borosilicate glass, soda-lime glass, alkali-alumino silicate glass, and lithium alumina silicate glass, for example. However, this is only an illustrative embodiment, and a material of the target TG is not limited thereto.

The guide unit 113 may be disposed on the laser support portion 111, and may be disposed on opposite sides to be spaced apart from each other with the laser stage 112 therebetween. In an embodiment, two guide units 113 may be provided to be spaced apart from each other in the second direction (e.g., the y-axis direction), for example. Each guide unit 113 may extend in the first direction (e.g., the x-axis direction), and an extension length of the guide unit 113 in the first direction (e.g., the x-axis direction) may be greater than at least a length of an edge of the target TG in the first direction (e.g., the x-axis direction).

The moving unit 114 may move the optical unit OP relative to the laser stage 112. The moving unit 114 may move the optical unit OP in the first direction (e.g., the x-axis direction), the second direction (e.g., the y-axis direction), and a third direction (e.g., a z-axis direction). The third direction (e.g., the z-axis direction) may intersect the first direction (e.g., the x-axis direction) and the second direction (e.g., the y-axis direction). The moving unit 114 may include a first moving unit 1141, a second moving unit 1142, and a third moving unit 1143.

The first moving unit 1141 may move the optical unit OP along the first direction (e.g., the x-axis direction). The guide unit 113 may guide the first moving unit 1141 to linearly move along an extension direction of the guide units 113. Each of the guide units 113 may include a linear motion rail, for example.

The first moving unit 1141 may linearly reciprocate along the first direction (e.g., the x-axis direction). The first moving unit 1141 may include a pillar member 1141a and a horizontal member 1141b. Although each of the pillar member 1141a and the horizontal member 1141b has a rectangular bar shape in FIG. 2, a shape of each of the pillar member 1141a and the horizontal member 1141b is not limited thereto.

The pillar member 1141a of the first moving unit 1141 may extend in the third direction (e.g., the z-axis direction). In an embodiment, two pillar members 1141a may be provided and may be disposed on opposite sides with the laser stage 112 therebetween, for example. The pillar members 1141a may move along the extension direction of the guide units 113, that is, the first direction (e.g., the x-axis direction). In an embodiment, the pillar members 1141a may be manually linearly moved or may be automatically linearly moved by a motor cylinder or the like. In an embodiment, the pillar members 1141a may be automatically linearly moved by a linear motion block that moves along linear motion rail, for example.

The horizontal member 1141b of the first moving unit 1141 may extend along the second direction (e.g., the y-axis direction) between the pillar members 1141a. Opposite ends of the horizontal member 1141b may be connected to upper portions of the pillar members 1141a. The horizontal member 1141b may include a first groove area 11411 extending along an extension direction of the horizontal member 1141b, that is, the second direction (e.g., the y-axis direction). The first groove area 11411 may be disposed on a side surface of the horizontal member 1141b. In an embodiment, the first groove area 11411 may be disposed on one of side surfaces of the first moving unit 1141 facing the second direction (e.g., the y-axis direction), for example. The first groove area 11411 may guide the second moving unit 1142 to linearly reciprocate along an extension direction of the first groove area 11411.

The second moving unit 1142 may move the optical unit OP along the second direction (e.g., the y-axis direction). The second moving unit 1142 may linearly move along the second direction (e.g., the y-axis direction). The second moving unit 1142 may be movably connected to one side surface of the horizontal member 1141b of the first moving unit 1141. In an embodiment, the second moving unit 1142 may be disposed on a side surface of the first moving unit 1141 where the first groove area 11411 is disposed, for example. The second moving unit 1142 may linearly reciprocate in the second direction (e.g., the y-axis direction) along the first groove area 11411. In an embodiment, the second moving unit 1142 may include a linear motor.

The third moving unit 1143 may move the optical unit OP along the third direction (e.g., the z-axis direction). The third moving unit 1143 may be disposed on a side of the second moving unit 1142 and may linearly reciprocate along the third direction (e.g., the z-axis direction). In an embodiment, the third moving unit 1143 may be disposed on a bottom surface of the second moving unit 1142, for example. The bottom surface of the second moving unit 1142 may be a surface of the second moving unit 1142 facing the laser stage 112.

The optical unit OP may be disposed over the laser stage 112 and may irradiate the laser LA toward the target TG. In detail, the optical unit OP may be fixed to one side of the third moving unit 1143. Accordingly, the optical unit OP may be moved by the moving unit 114 in the first direction (e.g., the x-axis direction), the second direction (e.g., the y-axis direction), and the third direction (e.g., the z-axis direction).

The laser controller 131 may control the laser irradiation unit 11. In detail, the laser controller 131 may control the moving unit 114 and the optical unit OP.

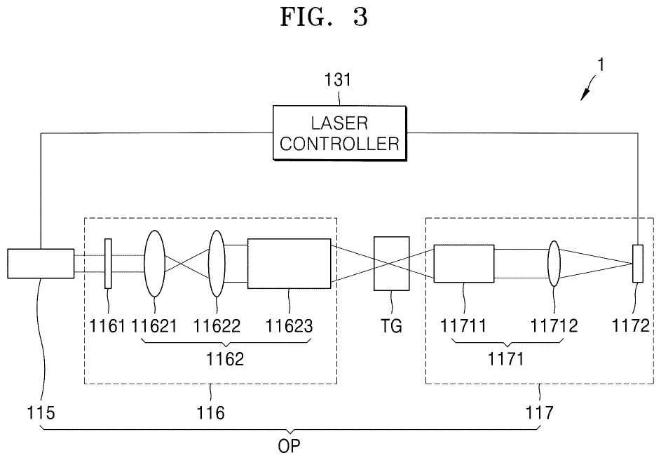

FIG. 3 is a cross-sectional view schematically illustrating an embodiment of a part of the apparatus 1 for manufacturing a display apparatus.

In detail, FIG. 3 illustrates the optical unit OP and the laser controller 131 of the apparatus for manufacturing a display apparatus.

Referring to FIG. 3, the optical unit OP may include a laser generating unit 115, a laser adjusting unit 116, and a laser measuring unit 117.

The laser generating unit 115 may generate the laser LA. The laser generating unit 115 may generate and output a laser beam having a predefined wavelength. In an embodiment, the laser LA generated by the laser generating unit 115 may be a femtosecond laser LA having a wavelength in a visible or near-infrared region and a short pulse width, for example. In an embodiment, the laser generating unit 115 may generate a solid laser beam including at least one of a ruby laser beam, an Nd:YAG laser beam, and a Ti:Sapphire laser beam, for example. In an embodiment, the laser generating unit 115 may generate a liquid laser beam including a dye laser beam, for example. In an embodiment, the laser generating unit 115 may generate a gas laser beam including at least one of a CO₂ laser beam, a He—Ne laser beam, an Ar+ laser beam, and an excimer laser beam, for example. In an embodiment, the laser generating unit 115 may generate an ultraviolet (“UV”) laser beam, for example. However, this is only an illustrative embodiment, and a type of the laser LA generated by the laser generating unit 115 is not limited thereto and may vary according to a type of the target TG or a processing method of the target TG.

The laser LA generated by the laser generating unit 115 may be incident on the laser adjusting unit 116. The laser LA incident on the laser adjusting unit 116 may pass through the laser adjusting unit 116 and may be irradiated to the target TG. The laser adjusting unit 116 may adjust characteristics of the laser LA generated by the laser generating unit 115 for efficient processing of the target TG. In an embodiment, the laser adjusting unit 116 may include a wavelength plate 1161 and a first lens unit 1162, for example.

The wavelength plate 1161 may change a polarization state of the laser LA. The wavelength plate 1161 may generate a predetermined optical path difference in the laser LA. In an embodiment, the wavelength plate 1161 may include at least one of a quarter-wave plate, a half-wave plate, and a full-wave plate, for example.

The first lens unit 1162 may focus or disperse the laser LA. The first lens unit 1162 may include a 1-1 lens 11621, a 1-2 lens 11622, and a 1-3 lens 11623. In an embodiment, each of the 1-1 lens 11621 and the 1-2 lens 11622 may include a convex lens, for example. The laser LA may sequentially pass through the 1-1 lens 11621 and the 1-2 lens 11622. A shape and size of a cross-section of the laser LA may be adjusted by adjusting a radius of curvature of each of the 1-1 lens 11621 and the 1-2 lens 11622 and a distance between the 1-1 lens 11621 and the 1-2 lens 11622. The 1-3 lens 11623 may function as an objective lens. The laser LA passing through the 1-3 lens 11623 may be incident on the target TG. The 1-3 lens 11623 may include at least one of a convex lens and a concave lens.

In an embodiment, the wavelength plate 1161, the 1-1 lens 11621, the 1-2 lens 11622, and the 1-3 lens 11623 may be sequentially arranged along a direction in which the laser LA travels, for example. Accordingly, the laser LA generated by the laser generating unit 115 may sequentially pass through the wavelength plate 1161, the 1-1 lens 11621, the 1-2 lens 11622, and the 1-3 lens 11623. However, this is only an illustrative embodiment, and an arrangement of the laser adjusting unit 116 is not limited thereto.

The laser measuring unit 117 may measure characteristics of the laser LA. The laser measuring unit 117 may include a second lens unit 1171 and a laser sensor unit 1172. The laser LA passing through the target TG may pass through the second lens unit 1171 and may reach the laser sensor unit 1172. The second lens unit 1171 may include a 2-1 lens 11711 and a 2-2 lens 11712.

The 2-1 lens 11711 may function as an objective lens. The laser LA passing through the 2-1 lens 11711 may be incident on the 2-2 lens 11712. The 2-1 lens 11711 may include at least one of a convex lens and a concave lens. The 2-2 lens 11712 may include a tube lens. In an embodiment, the 2-2 lens 11712 may include a convex lens. The 2-2 lens 11712 may focus or disperse the laser LA, for example. The laser LA passing through the 2-2 lens 11712 may be imaged on the laser sensor unit 1172.

The laser sensor unit 1172 may include an optical sensor. The laser sensor unit 1172 may receive the laser LA and may measure at least one of image information, an intensity, and a wavelength of the laser LA. The laser sensor unit 1172 may include at least one of an image sensor, an optoelectronic sensor, and an optical fiber sensor.

The laser generating unit 115 and the laser adjusting unit 116 may be disposed on the moving unit. The laser measuring unit 117 may be disposed on the laser stage. The laser LA generated by the laser generating unit 115 may pass through the laser adjusting unit 116 and the target TG and may reach the laser measuring unit 117.

Referring to FIGS. 2 and 3, the laser controller 131 may control the laser generating unit 115. The laser controller 131 may control characteristics of the laser LA output from the laser generating unit 115. In an embodiment, the laser controller 131 may control at least one of output power, intensity, period, and output timing of the laser LA output from the laser generating unit 115, for example. In an embodiment, the laser LA may be a Bessel beam or a multi-focal beam, for example. In an embodiment, the laser LA may have a wavelength of 1.3 micrometers (μm) to 2.5 μm and a pulse width of 1 nanosecond (ns) to 200 ns, for example. However, this is only an illustrative embodiment, and a configuration of the optical unit OP and characteristics of the laser LA are not limited thereto.

Also, the laser controller 131 may control the moving unit 114. In an embodiment, the laser controller 131 may control the third moving unit 1143, for example. The laser controller 131 may adjust the laser generating unit 115 and a distance based on information measured by the laser measuring unit 117. That is, the laser irradiation unit 11 may perform an auto-focus function due to the laser controller 131.

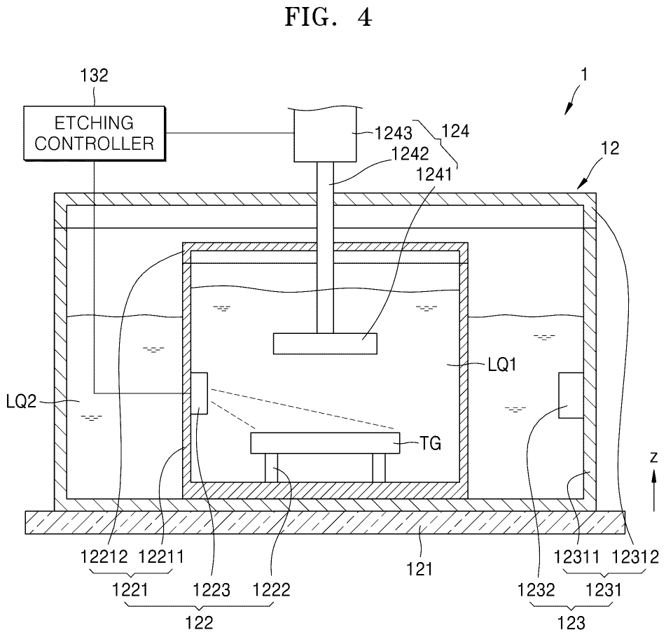

FIG. 4 is a cross-sectional view schematically illustrating an embodiment of a part of the apparatus 1 for manufacturing a display apparatus.

In detail, FIG. 4 illustrates the etching unit 12 and the etching controller 132 of the apparatus 1 for manufacturing a display apparatus.

Referring to FIG. 4, the etching unit 12 may include an etching support portion 121, an etching module 122, an ultrasonic module 123, and a stirring module 124.

The etching support portion 121 may support the etching module 122, the ultrasonic module 123, and the stirring module 124. The etching support portion 121 may have a plane defined by the first direction (e.g., the x-axis direction) and the second direction (e.g., the y-axis direction).

The etching module 122 may include a first chamber 1221, an etching stage 1222, and a target sensor unit 1223.

The first chamber 1221 may form an outer shape of the etching module 122. The first chamber 1221 may provide an internal space where the target TG is etched. A first liquid LQ1 that is an etching solution may be stored in the first chamber 1221. The internal space provided by the first chamber 1221 may be sealed. The first chamber 1221 may include a polyacrylic compound, a polyimide-based compound, a fluorine-based carbon compound such as polytetrafluoroethylene (e.g., Teflon®), or a benzocyclobutene compound. However, this is only an illustrative embodiment, and a material of the first chamber 1221 is not limited thereto. In an embodiment, the first chamber 1221 may include glass, for example.

The first chamber 1221 may include a 1-1 chamber 12211 and a 1-2 chamber 12212. The first liquid LQ1 may be stored in the 1-1 chamber 12211. The etching stage 1222 may be disposed inside the 1-1 chamber 12211. The 1-2 chamber 12212 may be disposed on one side of the 1-1 chamber 12211 and may seal the 1-1 chamber 12211. In an embodiment, the 1-2 chamber 12212 may be disposed on the 1-1 chamber 12211. The 1-2 chamber 12212 may be detachable from the 1-1 chamber 12211, for example. The 1-2 chamber 12212 may function as an opening/closing member of the first chamber 1221.

The etching stage 1222 may be disposed inside the first chamber 1221. In an embodiment, the etching stage 1222 may be supported by the first chamber 1221, for example. The etching stage 1222 may be fixed to the first chamber 1221. The target TG may be seated on the etching stage 1222.

The target sensor unit 1223 may measure a state of a surface of the target TG. In an embodiment, the target sensor unit 1223 may include an image sensor, for example. The target sensor unit 1223 may measure image information of the target TG by capturing an image of the surface of the target TG. The target sensor unit 1223 may be disposed inside the first chamber 1221. In an embodiment, the target sensor unit 1223 may be disposed inside the 1-1 chamber 12211, for example. However, this is only an illustrative embodiment, and an arrangement of the target sensor unit 1223 is not limited thereto. In an embodiment, the target sensor unit 1223 may be disposed inside the 1-2 chamber 12212 or may be disposed outside the first chamber 1221 to capture an image of the target TG, for example.

The first liquid LQ1 may be an acidic etching solution or a basic etching solution. In an embodiment, the first liquid LQ1 may be an acidic etching solution including at least one of hydrogen fluoride (“HF”), hydrochloric acid (“HCl”), H₂SO₄, aluminum bifluoride, and HNO₃, for example. In an embodiment, the first liquid LQ1 may be a solution in which HF and HCl are mixed at a ratio of 7:3, for example. In an embodiment, the first liquid LQ1 may be a basic etching solution including at least one of KOH and NaOH. However, this is only an illustrative embodiment, and a material of the first liquid LQ1 may vary according to a type of the target TG, for example.

The ultrasonic module 123 may generate ultrasonic waves to vibrate the etching module 122. The ultrasonic module 123 may apply vibration to the etching module 122 by ultrasonic waves. The ultrasonic module 123 may include a second chamber 1231 and an ultrasonic generator 1232.

The second chamber 1231 may form an outer shape of the ultrasonic module 123. The second chamber 1231 may provide an internal space where the etching module 122 is disposed. The etching module 122 may be accommodated in the second chamber 1231. The internal space provided by the second chamber 1231 may be sealed. A second liquid LQ2 may be stored in the second chamber 1231. The second liquid LQ2 may include water (H₂O). At least a part of the etching module 122 may be immersed in the second liquid LQ2.

The second chamber 1231 may include a 2-1 chamber 12311 and a 2-2 chamber 12312. The 2-1 chamber 12311 may store the etching module 122 and the second liquid LQ2. The 2-2 chamber 12312 may be disposed on one side of the 2-1 chamber 12311 and may seal the 2-1 chamber 12311. In an embodiment, the 2-2 chamber 12312 may be disposed on the 2-1 chamber 12311, for example. The 2-2 chamber 12312 may be detachable from the 2-1 chamber 12311. The 2-2 chamber 12312 may function as an opening/closing member of the second chamber 1231.

The ultrasonic generator 1232 may generate ultrasonic waves. The ultrasonic generator 1232 may vibrate the second liquid LQ2. An oscillation frequency of the ultrasonic generator 1232 may be 28 kilohertz (kHz) to 500 kHz. The ultrasonic generator 1232 may be disposed inside the second chamber 1231. In an embodiment, the ultrasonic generator 1232 may be disposed inside the 2-1 chamber 12311, for example. However, this is only an illustrative embodiment, and an arrangement of the ultrasonic generator 1232 is not limited thereto. In an embodiment, the ultrasonic generator 1232 may be disposed inside the 2-2 chamber 12312, for example.

The stirring module 124 may stir the first liquid LQ1 stored in the first chamber 1221 of the etching module 122. The stirring module 124 may include a blade 1241, a driving shaft 1242, and a driving unit 1243.

The blade 1241 may be disposed inside the first chamber 1221 of the etching module 122. At least a part of the blade 1241 may be immersed in the first liquid LQ1.

In an embodiment, the blade 1241 may be provided in a propeller shape, for example. However, this is only an illustrative embodiment, and a shape of the blade 1241 may vary according to a desired design condition. The blade 1241 may linearly move and/or rotate. In an embodiment, the blade 1241 may linearly reciprocate in the third direction (e.g., the z-axis direction), for example. In an embodiment, the blade 1241 may rotate in the third direction (e.g., the z-axis direction), for example. However, this is only an illustrative embodiment, and the blade 1241 may vibrate.

The driving shaft 1242 may connect the blade 1241 to the driving unit 1243. The driving shaft 1242 may have one side fixed to the blade 1241 and an opposite side fixed to the driving unit 1243. The driving unit 1243 may provide a driving force to move the blade 1241. The driving force of the driving unit 1243 may be transmitted to the blade 1241 through the driving shaft 1242. The driving unit 1243 may linearly move, rotate, or vibrate the driving shaft 1242.

As shown in FIG. 4, the driving unit 1243 may be disposed outside the second chamber 1231, and the driving shaft 1242 may pass through the first chamber 1221 and a third chamber to connect the blade 1241 to the driving unit 1243. However, this is only an illustrative embodiment, and unlike in FIG. 4, the driving unit 1243 and the driving shaft 1242 may be disposed inside the first chamber 1221.

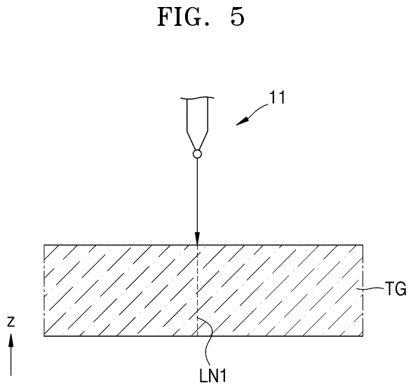

FIG. 5 is a cross-sectional view schematically illustrating an embodiment of a part of the target TG.

In detail, FIG. 5 is a cross-sectional view illustrating the target TG to which the laser LA is irradiated by the laser irradiation unit 11.

Referring to FIGS. 2 and 5, the laser irradiation unit 11 may irradiate the laser LA to the target TG.

In a state where the target TG is seated on the laser stage 112, the optical unit OP may irradiate the laser LA to the target TG. In this case, the laser LA may be a femtosecond laser, and the target TG may be a transparent material having a Kerr effect. As the laser LA is irradiated to the target TG, plasma may be generated long along a thickness direction (e.g., the z-axis direction) of the target TG. That is, a filamentation phenomenon may occur in the target TG. Accordingly, microcracks may occur in the target TG along a first line (also referred to as a first imaginary line) LN1 extending in the thickness direction (e.g., the z-axis direction) of the target TG.

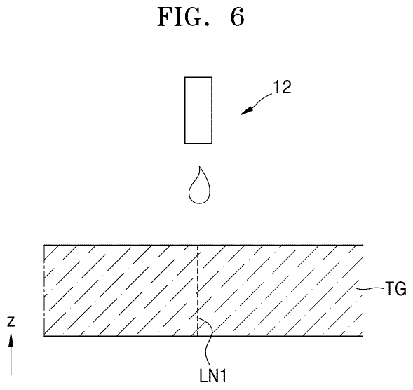

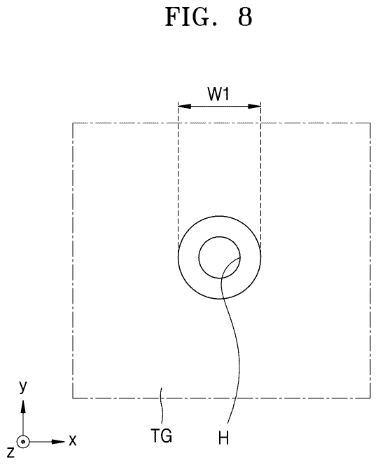

FIGS. 6 and 7 are cross-sectional views schematically illustrating an embodiment of a part of the target TG. FIG. 8 is a plan view schematically illustrating an embodiment of a part of the target TG.

In detail, FIG. 6 illustrates the target TG before being etched by the etching unit 12. FIGS. 7 and 8 illustrate the target TG after being etched by the etching unit 12.

Referring to FIGS. 4, and 6 to 8, the etching unit 12 may etch the target TG.

When the target TG is seated on the stage, the target TG may be immersed in the first liquid LQ1 that is an etching solution. Accordingly, the target TG may be etched along the first line LN1.

In this case, the ultrasonic module 123 may generate ultrasonic waves to vibrate the second liquid LQ2. Accordingly, the etching module 122 at least partially immersed in the second liquid LQ2 may vibrate. Impurities mixed in the first liquid LQ1 generated by etching the target TG may be decomposed or dispersed by the ultrasonic module 123.

Also, the stirring module 124 may stir the first liquid LQ1. Accordingly, the first liquid LQ1 may flow due to the stirring module 124. Impurities mixed in the first liquid LQ1 generated by etching the target TG may be dispersed by the stirring module 124. That is, a concentration of impurities around the target TG may be reduced.

In summary, the target TG may be efficiently etched by operations of the ultrasonic module 123 and the stirring module 124.

Accordingly, the hole H may be defined in the target TG around the first line LN1. The hole H may extend along the first line LN1 in the third direction (e.g., the z-axis direction). The hole H may have a portion whose width W1 gradually decreases from a surface of the target TG toward the center. As etching of the target TG proceeds, the width W1 of the hole H defined in the target TG may gradually increase.

The etching controller 132 may calculate an etching rate of the target TG based on information measured by the target sensor unit 1223. The target sensor unit 1223 may measure a state of the surface of the target TG. The etching controller 132 may receive information measured by the target sensor unit 1223 and may measure a time taken for the hole H to be defined in the target TG. That is, the etching controller 132 may calculate an etching rate by measuring a time taken for the hole H to pass through the target TG. An etching rate may increase as a time taken for the hole H to be defined in the target TG decreases.

The etching controller 132 may calculate an etching accuracy of the target TG based on information measured by the target sensor unit 1223. The target sensor unit 1223 may measure a state of the surface of the target TG. The etching controller 132 may receive information measured by the target sensor unit 1223, and may calculate an etching accuracy of the target TG by calculating an increment in the width W1 of the hole H over time. That is, the etching controller 132 may calculate an etching accuracy based on an increment in the width W1 of the hole H over time. As an increment in the width W1 of the hole H over time decreases, an etching accuracy of the target TG may increase. As an etching accuracy of the target TG increases, an etching selectivity may increase.

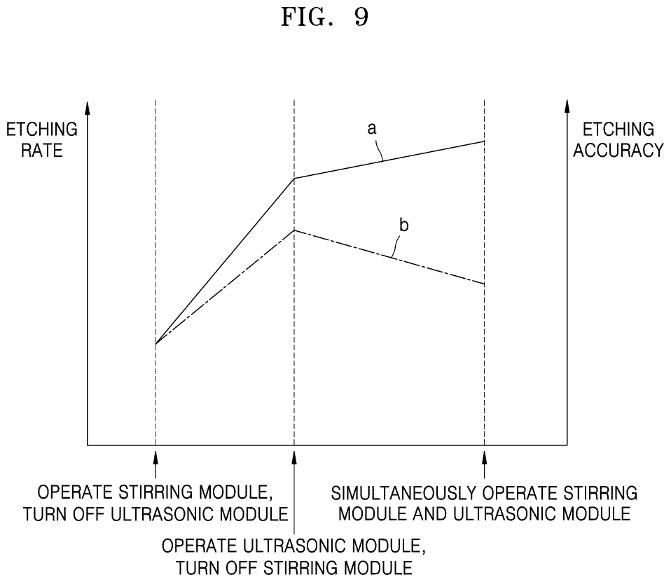

FIG. 9 is a graph illustrating an embodiment of an etching rate and an etching accuracy of the target TG.

In detail, a line a is a graph showing an etching rate, and a line b is a graph showing an etching accuracy.

A method of calculating an etching rate and an etching accuracy has been described with reference to FIGS. 4, and 6 to 8, and thus, a detailed description thereof will be omitted.

First, regarding an etching rate, it may be found that an etching rate when the ultrasonic module 123 operates and the stirring module 124 is turned off is higher than that when the stirring module 124 operates and the ultrasonic module 123 is turned off. Also, it may be found that an etching rate is the highest when the stirring module 124 and the ultrasonic module 123 simultaneously operate.

Regarding an etching accuracy, it may be found that an etching accuracy when the ultrasonic module 123 operates and the stirring module 124 is turned off is higher than that when the stirring module 124 operates and the ultrasonic module 123 is turned off. Also, it may be found that an etching accuracy when the stirring module 124 and the ultrasonic module 123 simultaneously operate is higher than that when the stirring module 124 operates and the ultrasonic module 123 is turned off. Also, it may be found that an etching accuracy when the stirring module 124 and the ultrasonic module 123 simultaneously operate is lower than that when the ultrasonic module 123 operates and the stirring module 124 is turned off.

In conclusion, it may be found that an etching rate and an etching accuracy when the ultrasonic module 123 operates and the stirring module 124 is turned off are higher than those when the stirring module 124 operates and the ultrasonic module 123 is turned off. That is, operating the ultrasonic module 123 may be advantageous in terms of both an etching rate and an etching accuracy.

However, when the stirring module 124 and the ultrasonic module 123 simultaneously operate, an etching rate may be higher but an etching accuracy may be lower than those when the ultrasonic module 123 operates and the stirring module 124 is turned off. Accordingly, the ultrasonic module 123 should always operate, but the stirring module 124 should operate or be turned off according to a desired etching accuracy.

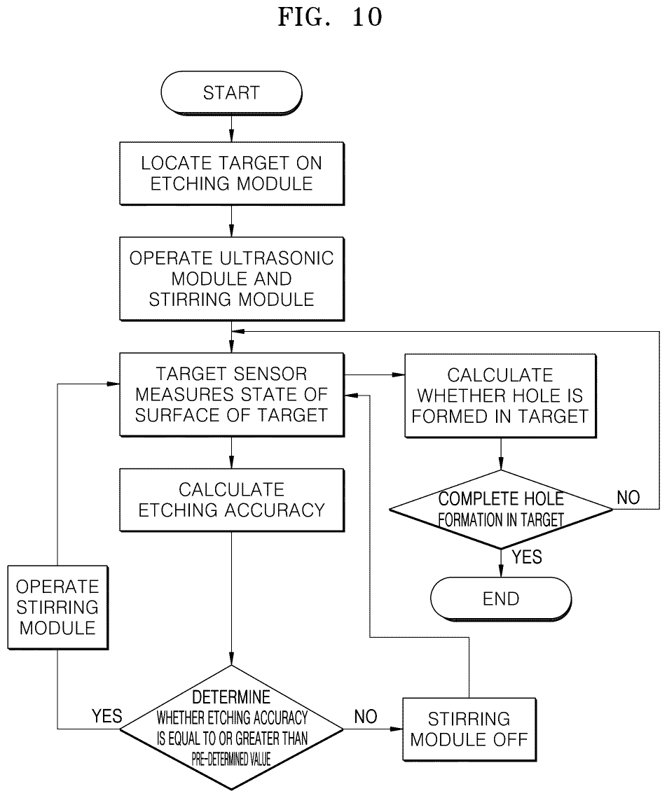

FIG. 10 is a flowchart illustrating an embodiment of a process of etching the target TG.

Referring to FIG. 10, a schematic algorithm for etching the target TG is illustrated.

First, the target TG may be disposed on the etching module 122. The target TG may be seated on the etching stage 1222, and the target TG may be immersed in the first liquid LQ1. Next, the ultrasonic module 123 and the stirring module 124 may operate. Accordingly, the target TG may be efficiently etched.

The target sensor unit 1223 may measure a state of a surface of the target TG. Information measured by the target sensor unit 1223 may be transmitted to the etching controller 132.

The etching controller 132 may calculate an etching accuracy based on the information measured by the target sensor unit 1223. The etching controller 132 may determine whether the etching accuracy is equal to or greater than a pre-determined value. The etching controller 132 may control an operation of the stirring module 124 based on the etching accuracy.

When the etching accuracy determined by the etching controller 132 is equal to or greater than the pre-determined value, the etching controller 132 may keep the stirring module 124 operating. That is, when the etching accuracy is equal to or greater than the pre-determined value, the etching controller 132 may operate each of the ultrasonic module 123 and the stirring module 124. Next, a process in which the target sensor unit 1223 measures a state of the surface of the target TG, a process of calculating an etching accuracy, and a process of determining whether the etching accuracy is equal to or greater than a pre-determined value may be repeated.

When the etching accuracy determined by the etching controller 132 is less than the pre-determined value, the etching controller 132 may turn off the stirring module 124. That is, when the etching accuracy is less than the pre-determined value, the etching controller 132 may operate the ultrasonic module 123 and may turn off the stirring module 124. Next, a process in which the target sensor unit 1223 measures a state of the surface of the target TG, a process of calculating an etching accuracy, and a process of determining whether the etching accuracy is equal to or greater than a pre-determined value may be repeated.

Such a process of operating and turning off the stirring module 124 according to an etching accuracy may be repeated until the hole H is formed in the target TG.

The etching controller 132 may calculate whether the hole H is formed in the target TG based on information measured by the target sensor unit 1223. That is, the etching controller 132 may determine whether the hole H passes through the target TG. When the etching controller 132 determines that the hole H is formed in the target TG, the process of etching the target TG may end. When the etching controller 132 determines that the hole H is formed in the target TG, the etching controller 132 may turn off the ultrasonic module 123 and the stirring module 124.

When the etching controller 132 determines that the hole H is not yet formed in the target TGt, the process of etching the target TG may be maintained. Accordingly, a process in which the target sensor unit 1223 measures a state of the surface of the target TG and a process of calculating whether the hole H is formed in the target TG may be repeated.

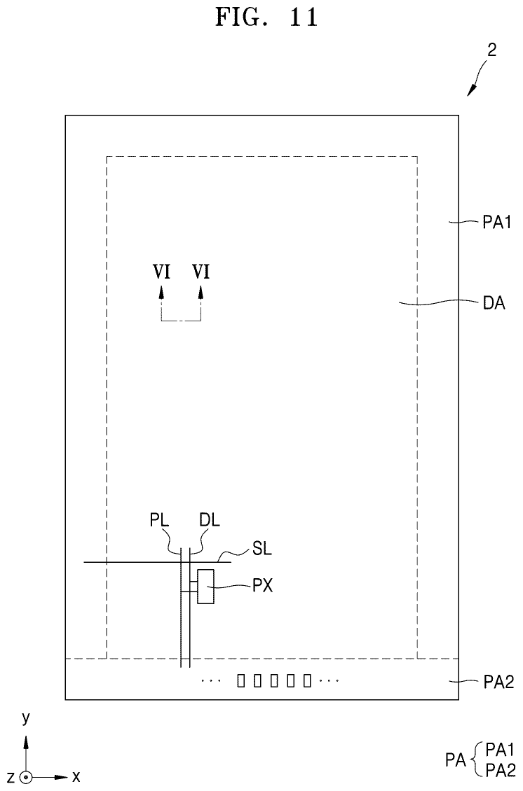

FIG. 11 is a schematic plan view illustrating an embodiment of a display apparatus 2.

Referring to FIG. 2, the display apparatus 2 may include a display area DA and a peripheral area PA disposed outside the display area DA. In FIG. 11, the display area DA has a quadrangular shape, e.g., rectangular shape. However, the disclosure is not limited thereto. The display area DA may have any of various shapes such as a circular shape, an elliptical shape, a polygonal shape, or a shape of a predetermined figure.

In this case, the display apparatus 2 may be an electronic device including a display panel. The electronic device may be a vehicle display device including a cluster, a center information display (“CID”), and/or a passenger display, a wearable electronic device that may be worn on a body part of a user, a medical electronic device, a robot, an electronic device for advertising or exhibition, and/or an electronic device for education.

The display area DA is a portion where an image is displayed, and a plurality of pixels PX may be disposed in the display area DA. Each pixel PX may include a display device such as an organic light-emitting diode. Each pixel PX may emit red light, green light, or blue light, for example. The pixel PX may be connected to a pixel circuit including a thin-film transistor (“TFT”) and a storage capacitor. The pixel circuit may be connected to a scan line SL through which a scan signal is transmitted, a data line DL that intersects the scan line SL and through which a data signal is transmitted, and a driving voltage line PL through which a driving voltage is supplied. The scan line SL may extend in the first direction (e.g., the x-axis direction), and the data line DL and the driving voltage line PL may extend in the second direction (e.g., the y-axis direction).

The pixel PX may emit light having a luminance corresponding to an electrical signal from the pixel circuit that is electrically connected to the pixel PX. The display area DA may display a predetermined image through light emitted from the pixel PX. For reference, as described above, the pixel PX may be defined as an emission area that emits light of any one of red, green, and blue colors.

The peripheral area PA may be a portion where the pixel PX is not disposed and an image is not displayed. The peripheral area PA may include a first peripheral area PA1 and a second peripheral area PA2. In the first peripheral area PA1, a power supply wiring for driving the pixel PX may be disposed. In the second peripheral area PA2, a pad unit PDP electrically connected to an electronic chip package including an integrated circuit (“IC”) chip or a printed circuit board including a driving circuit unit may be disposed.

The following will be described assuming that the display apparatus 2 in an embodiment is an organic light-emitting display apparatus. However, the display apparatus 2 of the disclosure is not limited thereto. In an embodiment, the display apparatus 2 of the disclosure may be an inorganic light-emitting display apparatus or an inorganic electroluminescent (“EL”) display apparatus, or a quantum dot light-emitting display apparatus, for example. In an embodiment, an emission layer of a display device included in the display apparatus 2 may include an organic material or an inorganic material, for example. Also, the display apparatus 2 may include an emission layer and quantum dots disposed in a path of light emitted from the emission layer.

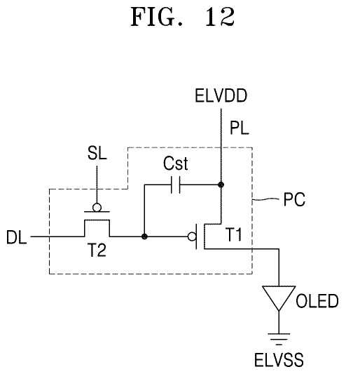

FIG. 12 is an equivalent circuit diagram illustrating an embodiment of a pixel circuit PC included in the display apparatus 2. The pixel circuit PC may be electrically connected to a display device, and one display device may correspond to one pixel PX. In an embodiment, the display device may be an organic light-emitting diode OLED, for example.

The pixel circuit PC may include a first transistor T1, a second transistor T2, and a storage capacitor Cst. The second transistor T2 that is a switching transistor may be connected to the scan line SL and the data line DL, and may be turned on by a switching signal input from the scan line SL to transmit a data signal input from the data line DL to the first transistor T1. The storage capacitor Cst may have one end electrically connected to the second transistor T2 and an opposite end electrically connected to the driving voltage line PL, and may store a voltage corresponding to a difference between a voltage received from the second transistor T2 and a driving power supply voltage ELVDD supplied to the driving voltage line PL.

The first transistor T1 that is a driving transistor may be connected to the driving voltage line PL and the storage capacitor Cst, and may control a magnitude of driving current flowing from the driving voltage line PL to the organic light-emitting diode OLED in response to a value of the voltage stored in the storage capacitor Cst. The organic light-emitting diode OLED may emit light having a predetermined luminance due to the driving current. A counter electrode 230 (refer to FIG. 13) of the organic light-emitting diode OLED may receive an electrode power supply voltage ELVSS.

Although the pixel circuit PC includes two transistors and one storage capacitor in FIG. 12, the disclosure is not limited thereto. In an embodiment, the number of transistors or the number of storage capacitors may be changed in various ways according to a design of the pixel circuit PC, for example.

FIG. 13 is a schematic cross-sectional view illustrating an embodiment of the display apparatus 2.

In detail, FIG. 13 is a cross-sectional view taken along line VI-VI of FIG. 11. That is, FIG. 13 is a cross-sectional view illustrating the display area DA (refer to FIG. 11) of the display apparatus 2.

Referring to FIGS. 11 and 13, the display apparatus 2 may include a first substrate SB1, a display unit DP, and a second substrate SB2 in the display area DA. In detail, the display unit DP may have a stacked structure of a pixel circuit layer PCL, a display element layer DEL, and an encapsulation layer 300.

The first substrate SB1 may have a multi-layer structure including a base layer including a polymer resin and an inorganic layer. In an embodiment, the first substrate SB1 may include a base layer including a polymer resin and a barrier layer of an inorganic insulating layer, for example. In an embodiment, the first substrate SB1 may include a first base layer 101, a first barrier layer 102, a second base layer 103, and a second barrier layer 104 which are sequentially stacked, for example. Each of the first base layer 101 and the second base layer 103 may include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate, cellulose triacetate (“TAC”), and/or cellulose acetate propionate (“CAP”). Each of the first barrier layer 102 and the second barrier layer 104 may include an inorganic insulating material such as silicon oxide, silicon oxynitride, and/or silicon nitride. The first substrate SB1 may be flexible. The target TG described with reference to FIGS. 1 to 10 may include the first substrate SB1.

The pixel circuit layer PCL is disposed on the first substrate SB1. In FIG. 13, the pixel circuit layer PCL includes a thin-film transistor TFT, and a buffer layer 1111, a first gate insulating layer 1112, a second gate insulating layer 1113, an inter-insulating layer 1114, a first planarization insulating layer 1115, and a second planarization insulating layer 1116 disposed under and/or over elements of the thin-film transistor TFT.

The buffer layer 1111 may reduce or block penetration of foreign materials, moisture, or external air from the bottom of the first substrate SB1 and may planarize the first substrate SB1. The buffer layer 1111 may include an inorganic insulating material such as silicon oxide, silicon oxynitride, or silicon nitride, and may have a single or multi-layer structure including the above material.

The thin-film transistor TFT on the buffer layer 1111 may include a semiconductor layer Act, and the semiconductor layer Act may include polysilicon (poly-Si). In an alternative embodiment, the semiconductor layer Act may include amorphous silicon (a-Si), an oxide semiconductor, or an organic semiconductor. The semiconductor layer Act may include a channel region C and a drain region D and a source region S disposed on opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first gate insulating layer 1112 between the semiconductor layer Act and the gate electrode GE may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second gate insulating layer 1113 may be provided to cover the gate electrode GE. The second gate insulating layer 1113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}), like the first gate insulating layer 1112. Zinc oxide (ZnO_{X}) may be zinc oxide (ZnO) and/or zinc peroxide (ZnO₂).

An upper electrode Cst2 of a storage capacitor Cst may be disposed on the second gate insulating layer 1113. The upper electrode Cst2 may overlap the gate electrode GE that is disposed below the upper electrode Cst2. In this case, the gate electrode GE and the upper electrode Cst2 overlapping each other with the second gate insulating layer 1113 therebetween may constitute the storage capacitor Cst. That is, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The inter-insulating layer 1114 may cover the upper electrode Cst2. The inter-insulating layer 1114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The inter-insulating layer 1114 may have a single or multi-layer structure including the above inorganic insulating material.

Each of a drain electrode DE and a source electrode SE may be disposed on the inter-insulating layer 1114. The drain electrode DE and the source electrode SE may be respectively connected to the drain region D and the source region S through contact holes defined in insulating layers under the drain electrode DE and the source electrode SE. Each of the drain electrode DE and the source electrode SE may include a material having excellent conductivity. Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The first planarization insulating layer 1115 may cover the drain electrode DE and the source electrode SE. The first planarization insulating layer 1115 may include an organic insulating material such as a general-purpose polymer (e.g., polymethyl methacrylate (“PMMA”) or polystyrene (“PS”)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or any combinations thereof.

The second planarization insulating layer 1116 may be disposed on the first planarization insulating layer 1115. The second planarization insulating layer 1116 may include the same material as that of the first planarization insulating layer 1115, and may include an organic insulating material such as a general-purpose polymer (e.g., PMMA or PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or any combinations thereof.

The display element layer DEL may be disposed on the pixel circuit layer PCL having the above structure. The display element layer DEL may include the organic light-emitting diode OLED as a display element (i.e., a light-emitting element), and the organic light-emitting diode OLED may have a structure in which a pixel electrode 210, an intermediate layer 220, and a common electrode 230 are stacked. The organic light-emitting diode OLED may emit red light, green light, or blue light, or may emit red light, green light, blue light, or white light, for example. The organic light-emitting diode OLED may emit light through an emission area, and the emission area may be defined as the pixel PX.

The pixel electrode 210 of the organic light-emitting diode OLED may be electrically connected to the thin-film transistor TFT through contact holes defined in the second planarization insulating layer 1116 and the first planarization insulating layer 1115 and a contact metal CM disposed on the first planarization insulating layer 1115.

The pixel electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the pixel electrode 210 may further include a film including or consisting of ITO, IZO, ZnO, or In₂O₃ over/under the reflective film.

A bank layer 1117 defining an opening 117OP through which a central portion of the pixel electrode 210 is exposed is disposed on the pixel electrode 210. The bank layer 1117 may include an organic insulating material and/or an inorganic insulating material. The opening 117OP may define the emission area of light emitted by the organic light-emitting diode OLED. In an embodiment, a size/width of the opening 117OP may correspond to a size/width of the emission area, for example. Accordingly, a size and/or a width of the pixel PX may depend on a size and/or a width of the opening 117OP of the bank layer 1117.

The intermediate layer 220 may include an emission layer 222 formed to correspond to the pixel electrode 210. The emission layer 222 may include a relatively high molecular weight organic material or a relatively low molecular weight organic material that emits light of a predetermined color. In an alternative embodiment, the emission layer 222 may include an inorganic light-emitting material or may include quantum dots.

In an embodiment, the intermediate layer 220 may include a first functional layer 221 and a second functional layer 223 respectively disposed under and over the emission layer 222. The first functional layer 221 may include a hole transport layer (“HTL”), or may include an HTL and a hole injection layer (“HIL”), for example. The second functional layer 223 that is an element disposed on the emission layer 222 may include an electron transport layer (“ETL”) and/or an electron injection layer (“EIL”). The first functional layer 221 and/or the second functional layer 223 may be a common layer entirely covering the first substrate SB1, like the common electrode 230 described below.

The common electrode 230 may be disposed on the pixel electrode 210 and may overlap the pixel electrode 210. The common electrode 230 may include or consist of a conductive material having a relatively low work function. In an embodiment, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloys thereof. In an alternative embodiment, the common electrode 230 may further include a layer including or consisting of ITO, IZO, ZnO, or In₂O₃ on the (semi) transparent layer including the above material. The common electrode 230 may be unitary to cover an entirety of the first substrate SB1.

The encapsulation layer 300 may be disposed on the display element layer DEL and may cover the display element layer DEL. The encapsulation layer 300 may include at least one inorganic encapsulation layer and at least one organic encapsulation layer. In an embodiment, in FIG. 13, the encapsulation layer 300 includes a first inorganic encapsulation layer 310, an organic encapsulation layer 320, and a second inorganic encapsulation layer 330 which are sequentially stacked.

Each of the first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. In embodiments, the polymer-based material may include an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

The second substrate SB2 may be disposed on the display unit DP. In detail, the second substrate SB2 may be disposed on the encapsulation layer 300. The second substrate SB2 may include a glass material. In an embodiment, the second substrate SB2 may include ultra-thin glass (“UTG”), for example. However, this is only an illustrative embodiment, and a material of the second substrate SB2 is not limited thereto. The target TG described with reference to FIGS. 1 to 10 may include the second substrate SB2.

While the disclosure has been particularly shown and described with reference to embodiments thereof, it will be understood by one of ordinary skill in the art that various modifications and equivalent other embodiments made be made from the disclosure. Accordingly, the true technical scope of the disclosure is defined by the technical spirit of the appended claims. By embodiments, a display apparatus may be processed rapidly and precisely.

Effects of the disclosure are not limited thereto, and other unmentioned effects will be clearly understood by one of ordinary skill in the art from the appended claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by one of ordinary skill in the art that various changes in form and details may be made therein without departing from the spirit and scope as defined by the following claims.

What is claimed is:

1. An apparatus for manufacturing a display apparatus from a target, the apparatus comprising:
an intense-light irradiation unit configured to irradiate an intense light to the target;
an etching unit configured to etch the target so that a hole is defined in the target to which the intense light is irradiated, the etching unit comprising:
an etching module comprising a first chamber in which a first liquid is stored as an etching solution, an etching stage on which the target is seated, and a target sensor unit configured to measure a state of a surface of the target;
an ultrasonic module configured to vibrate the etching module by generating ultrasonic waves; and
a stirring module configured to stir the first liquid; and
a controller comprising an etching controller configured to control the etching unit, calculate an etching accuracy of the target based on information measured by the target sensor unit, and control an operation of the stirring module, based on the etching accuracy.

2. The apparatus of claim 1, wherein the etching controller is further configured to,
when the etching accuracy is equal to or greater than a pre-determined value, operate each of the ultrasonic module and the stirring module.

3. The apparatus of claim 1, wherein the etching controller is further configured to, when the etching accuracy is less than a pre-determined value, operate the ultrasonic module and turn off the stirring module.

4. The apparatus of claim 1, wherein the etching controller is further configured to calculate the etching accuracy based on an increment in a width of the hole over time.

5. The apparatus of claim 1, wherein the target sensor unit comprises an image sensor.

6. The apparatus of claim 1, wherein the etching controller is further configured to calculate whether the hole is defined in the target based on information measured by the target sensor unit.

7. The apparatus of claim 6, wherein the etching controller is further configured to, when it is determined that the hole is defined in the target, turn off the ultrasonic module and the stirring module.

8. The apparatus of claim 1, wherein the first liquid comprises at least one of hydrogen fluoride and hydrochloric acid.

9. The apparatus of claim 8, wherein the first liquid comprises a solution in which hydrogen fluoride and hydrochloric acid are mixed at a ratio of 7:3.

10. The apparatus of claim 1, wherein the target comprises a transparent glass material.

11. An apparatus for manufacturing a display apparatus from a target, the apparatus comprising:
an intense-light irradiation unit configured to irradiate an intense light to generate microcracks in the target along an imaginary first line;
an etching unit configured to etch the target so that a hole is defined in the target around the imaginary first line, the etching unit comprising:
an etching module comprising a first chamber in which a first liquid is stored as an etching solution, an etching stage that is disposed in the first chamber and on which the target is seated, and a target sensor unit configured to measure a state of a surface of the target;
an ultrasonic module configured to vibrate the etching module by generating ultrasonic waves; and
a stirring module configured to stir the first liquid; and
a controller comprising an etching controller configured to control the etching unit.

12. The apparatus of claim 11, wherein the ultrasonic module comprises:
a second chamber in which the etching module is disposed and a second liquid is stored so that at least a part of the etching module is immersed; and
an ultrasonic generator disposed in the second chamber and configured to generate the ultrasonic waves so that the second liquid vibrates.

13. The apparatus of claim 11, wherein the stirring module comprises:
a blade at least partially immersed in the first liquid; and
a driving unit configured to provide a driving force to the blade so that the blade moves.

14. The apparatus of claim 11, wherein the etching controller is configured to
calculate an etching accuracy of the target based on information measured by the target sensor unit, and
control an operation of the stirring module, based on the etching accuracy.

15. The apparatus of claim 14, wherein the etching controller is further configured to, when the etching accuracy is equal to or greater than a pre-determined value, operate each of the ultrasonic module and the stirring module.

16. The apparatus of claim 14, wherein the etching controller is further configured to, when the etching accuracy is less than a pre-determined value, operate the ultrasonic module and turn off the stirring module.

17. The apparatus of claim 14, wherein the etching controller is further configured to calculate the etching accuracy based on an increment in a width of the hole over time.

18. The apparatus of claim 14, wherein the etching controller is further configured to calculate whether the hole is defined in the target based on information measured by the target sensor unit.

19. The apparatus of claim 18, wherein the etching controller is further configured to, when it is determined that the hole is defined in the target, turn off the ultrasonic module and the stirring module.

20. The apparatus of claim 11, wherein the target sensor unit comprises an image sensor.
